(19) United States
(12) Patent Application Publication
(10) Pub. No.: US 2007/0145584 A1
(43) Pub. Date: Jun. 28, 2007

(54) Printed wiring board, method for manufacturing same, and circuit device

(75) Inventors: Tatsuo Kataoka, Saitama (JP); Yoshikazu Akashi, Saitama (JP); Yutaka Iguchi, Tokyo (JP)

Correspondence Address: THE WEBB LAW FIRM, P.C., 700 KOPPERS BUILDING, 436 SEVENTH AVENUE, PITTSBURGH, PA, 15219, US

(73) Assignee: Mitsui Mining & Smelting Co., Ltd., Tokyo (JP)

(21) Appl. No.: 10/583,846

(22) PCT Filed: Dec. 10, 2004
(86) PCT No.: PCT/JP04/18500

§ 371 Date: Jun. 22, 2006

(30) Foreign Application Priority Data
Dec. 26, 2003 (JP) 2003-435685
Jul. 29, 2004 (JP) 2004-222185

(51) Int. Cl. H01L 23/48

(52) U.S. Cl. 257/736

(57) ABSTRACT

The printed wiring board comprises, on at least one surface of an insulating film, a base metal layer and a conductive metal layer formed on the base metal layer, and is characterized in that in a section of the wiring board the bottom width of the conductive metal layer is smaller than the top width of the base metal layer. The circuit device comprises the printed wiring board and an electronic part mounted thereon. The process for producing a printed wiring board comprises bringing a base metal layer and a conductive metal layer into contact with an etching solution capable of dissolving the conductive metal to form a wiring pattern and then sequentially bringing the resultant into contact with a first treating solution capable of dissolving the metal for forming the base metal layer, a microetching solution capable of selectively dissolving the conductive metal and a second treating solution having a different chemical composition from the first treating solution in this order.

### TECHNICAL FIELD

The present invention relates to a printed wiring board in which a wiring pattern is directly formed on a surface of an insulating film without interposing an adhesive, a process for producing the printed wiring board, and a circuit device mounted with an electronic part. More particularly, the present invention relates to a printed wiring board formed from a substrate of a two-layer structure consisting of an insulating film and a metal layer formed on a surface of the insulating film, a process for producing the printed wiring board, and a circuit device in which an electronic part is mounted on the printed wiring board.

### BACKGROUND ART

Wiring boards have been heretofore produced by the use of a copper-clad laminate in which a copper foil is laminated on a surface of an insulating film such as a polyimide film using an adhesive.

Such a copper-clad laminate is produced by thermally bonding a copper foil under pressure to an insulating film on a surface of which an adhesive layer is formed. In the production of the copper-clad laminate, therefore, the copper foil must be handled alone. However, the nerve of the copper foil is lowered as the thickness of the copper foil is decreased, and the lower limit of the thickness of the copper foil which can be handled alone is about 9 to 12 μm. In the case where a copper foil having a thickness smaller than this thickness is used, handling becomes very complicated, for example, it becomes necessary to use a copper foil with a support. Further, if a wiring pattern is formed using a copper-clad laminate in which such a thin copper foil is bonded to a surface of an insulating film with an adhesive, warpage deformation of the resulting printed wiring board is brought about by heat shrinkage of the adhesive that is used for bonding the copper foil. In particular, with miniaturization and lightening of electronic equipments, thinning and lightening of printed wiring boards have been also promoted, and it is becoming impossible that the copper-clad laminates of three-layer structure consisting of an insulating film, an adhesive and a copper foil meet such printed wiring boards.

Then, instead of the copper-clad laminates of three-layer structure, laminates of two-layer structure in which a metal layer is directly laminated on a surface of an insulating film without interposing an adhesive have been employed. Such laminates of two-layer structure are produced by depositing a seed layer metal on a surface of an insulating film such as a polyimide film by means of vapour deposition, sputtering or the like. On a surface of the metal thus deposited, copper is deposited by plating, then a photoresist is applied, exposed to light and developed, and then etching is performed, whereby a desired wiring pattern can be formed. The laminate of a two-layer structure is particularly suitable for producing an extremely fine wiring pattern having a wiring pattern pitch width of less than 30 μm because the metallic copper layer is thin.

By the way, in a patent document 1 (Japanese Patent Laid-Open Publication No. 188495/2003), there is disclosed an invention of a process for producing a printed wiring board comprising subjecting a metal coated polyimide film, which has a first metal layer formed on a polyimide film by a dry film-forming method and a second metal layer having conductivity that is formed by plating on the first metal layer, to etching to form a pattern, wherein after the etching, the etched surface is subjected to cleaning treatment with an oxidizing agent. In Example 5 of this patent document 1, an example comprising plasma depositing a nickel-chromium alloy in a thickness of 10 nm and then depositing copper in a thickness of 8 μm by plating is shown.

By the use of the thus formed metal coated polyimide film of a two-layer structure, a fine wiring pattern can be formed, but migration is liable to occur from the first metal layer of nickel, chromium or the like deposited on the polyimide film, and short-circuit attributable to migration is liable to occur between the neighboring wiring patterns. Especially when metals such as nickel and chromium are sputtered on the polyimide film, a part of the metals is bonded to the component that forms the polyimide film. The metal thus bonded to the polyimide component is hardly removed even when it is brought into contact with an etching solution, and the metal tends to remain on the surface of the polyimide film. In the case where such a metal remains on the surface of the polyimide film present between the wiring patterns, there is brought about a problem that short-circuit is liable to take place between the neighboring wiring patterns through the metal remaining on the polyimide film surface even if migration slightly occurs from the base metal layer that forms the wiring pattern.

As described in the above publication, a comb-shaped electrode is formed, and a wiring pattern for forming the comb-shaped electrode is subjected to plating. This plating is generally carried out as follows. The wiring pattern formed is coated with a solder resist ink in such a manner that the terminals (inner lead, outer lead) are exposed, then the solder resist ink is cured to form a solder resist layer, and the exposed terminals are plated. At the terminals formed through such steps as described in the above publication, however, it is difficult to effectively prevent occurrence of migration from the first metal layer formed on the polyimide film.

In paragraphs [0004] and [0005] of a patent document 2 (Japanese Patent Laid-Open Publication No. 282651/2003), it is described that a metal layer 1 made of an alloy of copper and a metal other than copper is provided on a surface of a flexible insulating film 2 in order to ensure adhesion strength between the flexible insulating film and a wiring pattern, then on a surface of the metal layer 1 a copper foil is arranged to form a composite, and from the composite a flexible wiring board is produced. It is further described that at the periphery of the lower part of the lead of the wiring pattern formed by the use of such a composite, the metal layer 1 remains as the unremoved portion as shown in FIG. 5, and it is also described that because of the unremoved portion, abnormal deposit 6 of the plating metal is formed. Moreover, it is described that at the abnormal deposit 6 of the plating metal, a crystal of tin grows and becomes a “whisker”, and because of the whisker, short-circuit takes place in the wiring pattern. That is to say, if the metal layer 1 provided to ensure adhesion strength of the wiring pattern is left as it is and if a tin plating layer is formed on the surface of the metal layer 1, a whisker is produced from the thus formed tin plating layer. In the document 2, therefore, the metal layer 1 is completely removed, as described in a paragraph [0023].

However, it is extremely difficult to completely remove the metal layer 1 from the outer periphery of the wiring pattern. In the process described in the patent document 2, the metal layer 1 remains as it is at the outer periphery of the lower part of the wiring pattern though the amount is trace, and production of whiskers from the tin plating layer attributable to the residual metal layer 1 cannot be completely prevented.

Patent document 1: Japanese Patent Laid-Open Publication No. 188495/2003

Patent document 2: Japanese Patent Laid-Open Publication No. 282651/2003

### DISCLOSURE OF THE INVENTION

### Problem to be Solved by the Invention

The present invention is intended to solve the problem characteristic of the printed wiring board using a metal coated polyimide film of a two-layer structure, namely, the problem of lowering of insulation resistance after application of a voltage that is specifically brought about by the use of a metal coated polyimide film of a two-layer structure wherein a metal layer is formed on a surface of an insulating film without interposing an adhesive.

That is to say, it is an object of the present invention to provide a process for producing a printed wiring board rarely suffering variation of an insulation resistance value, using a metal coated polyimide film of a two-layer structure.

It is another object of the invention to provide a printed wiring board rarely suffering variation of an insulation resistance value produced by the above process.

It is a further object of the invention to provide a circuit device wherein an electronic part is mounted on the above-mentioned printed wiring board.

### Means to Solve Problem

The printed wiring board of the present invention is a printed wiring board having, on at least one surface of an insulating film, a wiring pattern comprising a base metal layer and a conductive metal layer formed on the base metal layer, wherein in a section of the wiring pattern, a width of a bottom of the conductive metal layer is smaller than a width of a top of the base metal layer. The printed wiring board of the invention includes an embodiment having, on at least one surface of an insulating film, a wiring pattern comprising a base metal layer and a conductive metal layer formed on the base metal layer, wherein the base metal layer exposed as the side wall of the wiring pattern is concealed with a concealing plating layer.

The process for producing a printed wiring board of the present invention is a process comprising the steps of depositing a base metal layer on at least one surface of an insulating film, then depositing a conductive metal on the base metal layer surface to form a conductive metal layer and then selectively etching the base metal layer and the conductive metal layer to form a wiring pattern, wherein the base metal layer and the conductive metal layer are brought into contact with an etching solution capable of dissolving the conductive metal to form a wiring pattern, and thereafter the resultant is brought into contact with a first treating solution capable of dissolving the metal for forming the base metal layer, then brought into contact with a microetching solution capable of selectively dissolving the conductive metal and then brought into contact with a second treating solution having a different chemical composition from the first treating solution and acting on the base metal layer-forming metal with higher selectivity than on the conductive metal. The process for producing a printed wiring board of the present invention is preferably a process comprising the steps of depositing a base metal layer containing Ni and Cr on at least one surface of an insulating film, then depositing a conductive metal on the base metal layer surface to form a conductive metal layer and then selectively etching the base metal layer and the conductive metal layer to form a wiring pattern, wherein the base metal layer and the conductive metal layer are brought into contact with an etching solution capable of dissolving the conductive metal to form a wiring pattern, thereafter the resultant is brought into contact with a first treating solution capable of dissolving Ni of the metals for forming the base metal layer, and then the wiring pattern formed is brought into contact with a microetching solution capable of dissolving copper to retreat the conductive metal layer and thereby expose the base metal layer following the contour of the conductive metal layer around the wiring pattern and then brought into contact with a second treating solution capable of dissolving Cr or converting a trace amount of the residual Cr into a non-conductive film. Further, the process for producing a printed wiring board of the present invention is also a process comprising the steps of depositing a base metal layer on a surface of an insulating film, then depositing a conductive metal on the base metal layer surface to form a conductive metal layer and then selectively etching the base metal layer and the conductive metal layer to form a wiring pattern, wherein the base metal layer and the conductive metal layer are brought into contact with an etching solution capable of dissolving the conductive metal to form a wiring pattern, and thereafter the resultant is brought into contact with an etching solution capable of dissolving the metal for forming the base metal layer and then subjected to plating for concealing.

The circuit device of the present invention comprises the above-mentioned printed wiring board and an electronic part mounted thereon.

### EFFECT OF THE INVENTION

In the printed wiring board of the present invention, the bottom width of the conductive metal layer is made smaller than the top width of the base metal layer in a section of the wiring pattern, preferably the bottom width of the conductive metal layer is made smaller by usually 0.1 to 4 μm than the top width of the base metal layer which is in contact with the conducive metal layer in a section of the wiring pattern, and in addition, at least a side surface of the base metal layer present at the bottom of the wiring pattern may be plated for concealing. Consequently, migration from the base metal layer hardly occurs, and therefore, the printed wiring board of the invention very rarely suffers variation of a resistance value between terminals after application of a voltage.

In the present invention, the base metal layer present around the wiring pattern has been passivated, and therefore, no whisker is produced from a plating layer formed on the surface of the base metal layer.

In the circuit device of the present invention, the electrical resistance between the wiring patterns formed as above in the printed wiring board is stable in spite of a lapse of time, and therefore, the circuit device of the invention can be stably used for a long period of time.

### BRIEF DESCRIPTION OF THE DRAWINGS

FIG. 1 is a group of views showing sections of boards in an embodiment of the process for producing a printed wiring board of the present invention.

FIG. 2 is a group of views showing sections of boards in another embodiment of the process for producing a printed wiring board of the present invention.

FIG. 3 is a sectional view of an embodiment of the printed wiring board of the present invention.

FIG. 4 is a sectional view of another embodiment of the printed wiring board of the present invention.

FIG. 5 is a SEM photograph showing an edge of a wiring on an insulating film before microetching treatment.

FIG. 6 is a SEM photograph showing an edge of a wiring on an insulating film after microetching treatment.

FIG. 7 is a group of schematic views showing a wiring pattern before treatment with a first treating solution (FIG. 7(A)), a wiring pattern after treatment with a first treating solution (FIG. 7(B)) and a wiring pattern after microetching treatment (FIG. 7(C)).

### DESCRIPTION OF REFERENCE NUMERALS

11: insulating film

12: base metal layer

13: sputtering copper layer

14: plating copper layer

16: concealing plating layer

20: conductive metal layer (copper layer)

21: exposed portion of base metal layer

21a: protrusion of base metal layer

21b: residue of independent base metal layer

### BEST MODE FOR CARRYING OUT THE INVENTION

The printed wiring board of the invention is described in detail hereinafter in accordance with the production process.

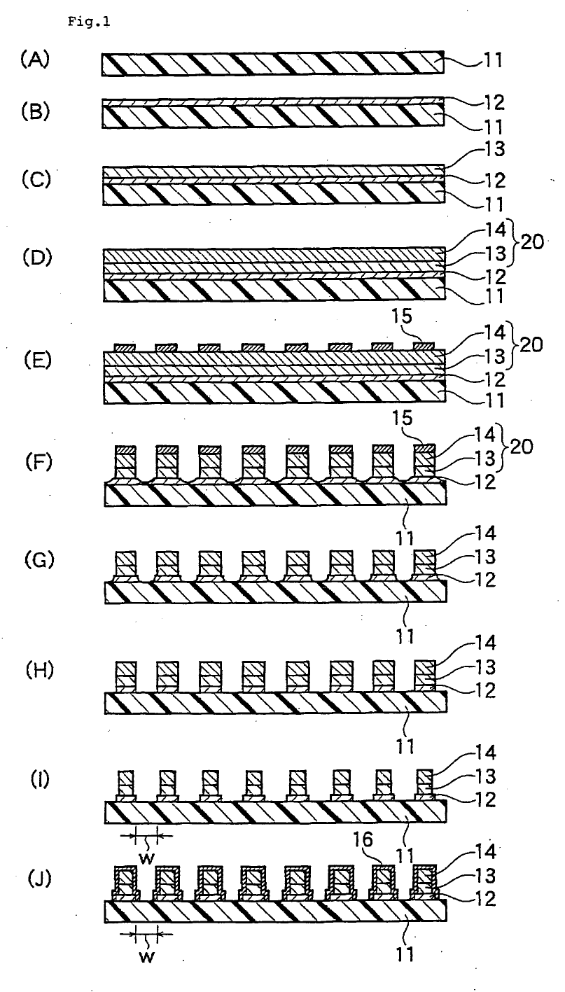

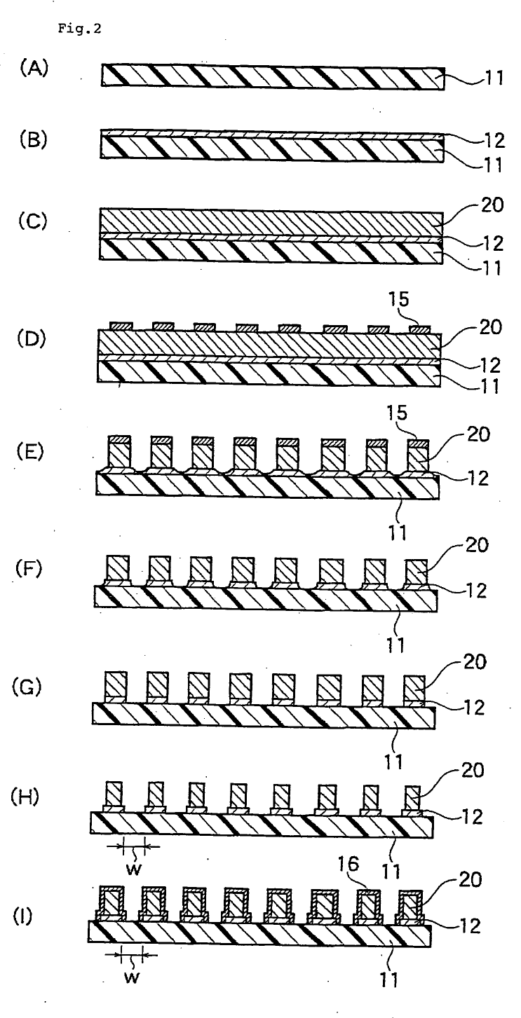

FIG. 1 and FIG. 2 are each a group of views showing sections of boards in the steps of the process for producing a printed wiring board of the invention. In the drawings attached, like members are given like numerals.

In the printed wiring board of the invention, a wiring pattern is formed on at least one surface of an insulating film, and therefore, a wiring pattern may be formed on one surface of an insulting film or may be formed on two surfaces of a front surface and a back surface of an insulating film. In an embodiment described below, a wiring pattern is formed on one surface of an insulating film, but a wiring pattern can be formed also on the other surface in a similar manner.

In the process for producing a printed wiring board of the invention, a polyimide film, a polyimidoamide film, polyester, polyphenylene sulfide, polyether imide, liquid crystal polymer or the like is employable as the insulating film 11 shown in FIG. 1(A) and FIG. 2(A). That is to say, the insulating film 11 has heat resistance of such a degree that it is not deformed by heat given when the later-described base metal layer 12 is formed. Further, the insulating film 11 has acid resistance and alkali resistance of such a degree that it is not corroded with an etching solution used for etching or an alkali solution used for cleaning. As the insulating film 11 having such properties, a polyimide film is preferable.

The insulating film 11 has an average thickness of usually 7 to 80 μm, preferably 7 to 50 μm, particularly preferably 15 to 40 μm. The printed wiring board of the invention is suitable as a thin board, so that it is preferable to use a thinner polyimide film. The surface of the insulating film 11 may have been subjected to surface roughening treatment using a hydrazine-KOH solution, plasma treatment or the like in order to enhance adhesion to the below-described base metal layer 13.

On at least one surface of the insulting film, a base metal is deposited to form a base metal layer 12, as shown in FIG. 1(B) and FIG. 2(B). The base metal layer 12 is formed on at least one surface of the insulating film 11 and serves to enhance adhesion between the insulating film and a conductive metal layer formed on the surface of the base metal layer 12.

Examples of the metals for forming the base metal layer 12 include copper, nickel, chromium, molybdenum, tungsten, silicon, palladium, titanium, vanadium, iron, cobalt, manganese, aluminum, zinc, tin and tantalum. These metals can be used singly or in combination. Of these metals, nickel, chromium or an alloy thereof is preferably used to form the base metal layer 12. It is preferable to form the base metal layer 12 on a surface of the insulating film 11 by a film-forming method of a dry process, such as vapour deposition or sputtering. The thickness of the base metal layer 12 is in the range of usually 1 to 100 nm, preferably 2 to 50 nm. The base metal layer 12 is provided for the purpose of stably forming a conductive layer 20 thereon and is preferably formed by causing a part of the base metal, which has kinetic energy of such a degree that it physically thrusts into the insulating film, to collide with the insulating film.

In the present invention, the base metal layer 12 is particularly preferably a sputtering layer of the above-mentioned base metal.

After the base metal layer 12 is formed as above, a conductive metal layer 20 is formed on the surface of the base metal layer 12, as shown in FIG. 2(D). The metal for forming the conductive metal layer 20 employable in the invention is, for example, copper or a copper alloy. The conductive metal layer 20 can be formed by a plating method. The plating method used herein is electroplating or electroless plating.

In the present invention, the thickness of such a conductive metal layer 20 as shown in FIG. 2(D) is in the range of usually 1 to 18 μm, preferably 2 to 12 μm.

In the present invention, after the base metal layer 12 is formed and before the conductive metal layer 20 is formed on the surface of the base metal layer 12, a sputtering metal layer 13 can be formed on the surface of the base metal layer 12 by the use of the same metal (e.g., copper) as that of the conductive metal layer 20 in the same manner as in the formation of the base metal layer 12, as shown in FIG. 1(C). For example, in the case where the base metal layer 12 is formed by sputtering using nickel and chromium and the conductive metal layer 20 is a copper layer, a sputtering copper layer can be formed as the sputtering metal layer 13.

In this case, the thickness of the sputtering copper layer 13 is in the range of usually 10 to 2000 nm, preferably 20 to 500 nm. The ratio between the average thickness of the base metal layer 12 and the thickness of the sputtering copper layer 13 is in the range of usually 1:20 to 1:100, preferably 1:25 to 1:60.

After the sputtering copper layer 13 is formed as above, a conductive metal layer is formed on the surface of the sputtering copper layer 13, as shown in FIG. 1(D). In FIG. 1(D), the conductive metal layer thus deposited is designated by numeral 14 (plating conductive metal layer). Although the conductive metal layer designated by numeral 14 can be formed by sputtering or vapour deposition, it is preferred to form the layer by a plating method such as electroplating or electroless plating. That is to say, the plating conductive metal layer 14 needs to have a thickness of a certain degree in order to form a wiring pattern, and by adopting the plating method such as electroplating or electroless plating, a conductive metal can be efficiently deposited. The average thickness of the plating conductive metal layer 14 thus formed is in the range of usually 0.5 to 40 μm, preferably 0.5 to 17.5 μm, more preferably 1.5 to 11.5 μm, and the total thickness of the sputtering copper layer 13 and the plating conductive metal layer 14 is in the range of usually 1 to 40 μm, preferably 1 to 18 μm, more preferably 2 to 12 μm. After the plating conductive metal layer 14 is formed, it is very difficult to find out a boundary between the sputtering copper layer 13 and the plating conductive metal layer 14 from their sectional structures. Especially when they are formed from the same conductive metal, they are united in a body, and in the present invention, therefore, these layers are put together and described as a “conductive metal layer 20” in the case where they do not need to be particularly distinguished.

After the conductive metal layer 20 is formed as above, the surface of the conductive metal layer 20 is coated with a photosensitive resin, and the photosensitive resin is exposed to light and developed to form a desired pattern 15 made of the photosensitive resin, as shown in FIG. 1(E) and FIG. 2(E). As the photosensitive resin, a photosensitive resin of such a type as is cured by irradiation with light may be used, or a photosensitive resin of such a type as is softened by irradiation with light may be used.

Then, using the pattern 15 formed from the photosensitive resin as a masking material, the conductive metal layer 20 is selectively etched to form a desired wiring pattern, as shown in FIG. 1(F) and FIG. 2(F).

The etching agent used herein is an agent for etching the conductive metal, and examples of such conductive metal etching agents include an etching solution containing ferric chloride as a major ingredient, an etching solution containing cupric chloride as a major ingredient, and an etching solution of sulfuric acid+hydrogen peroxide. The etching solution for the conductive metal can etch the conductive metal layer 20 with excellent selectivity to form a wiring pattern, and besides, it has a considerable etching function for the base metal present between the conductive metal layer 20 and the insulating film 11. Therefore, when etching is carried out using the above-mentioned conductive metal etching agent, the base metal layer 12 can be etched to such an extent that the base metal layer remains as an extremely thin layer of about several nm on the surface of the insulating film 11, as shown in FIG. 1(F) and FIG. 2(F). That is to say, between the wiring patterns, the base metal layer becomes an extremely thin layer, but below the wiring pattern formed from the conductive metal layer, the base metal layer is not etched and has the same thickness as the initial thickness.

The desired pattern 15 formed from the photosensitive resin in the formation of a wiring pattern is removed by, for example, alkali cleaning after the etching step and before the subsequent step.

In the present invention, before the base metal layer 12 is treated with a given treating solution in a manner described later, microetching, namely, etching of the surface of the conductive metal layer 20 that forms the wiring pattern and the base metal designated by numeral 12 is preferably carried out to remove an oxide film from their surfaces, as shown in FIG. 1(G). For the microetching, an etching solution usually used for etching the conductive metal is employable. For example, an etching solution used for pickling, such as HCl or H₂SO₄, is employable.

In the present invention, the conductive metal layer 20 is selectively etched, then microetching (pickling treatment) is carried out when needed, and thereafter, the resultant is treated with a first treating solution capable of dissolving Ni and a Ni alloy such as a Ni—Cr alloy for forming the base metal layer, as shown in FIG. 1(H). The expression “capable of dissolving Ni” means that Ni hardly remains but metals other than Ni partially remain (in case of a Ni—Cr alloy, Cr remains).

In the present invention, the first treating solution capable of dissolving Ni is, for example, a sulfuric acid/hydrochloric acid mixed solution having each concentration of about 5 to 15% by weight.

By the treatment with the first treating solution capable of dissolving Ni, a part of metals contained in the base metal layer is removed. In the treatment with the first treating solution capable of dissolving Ni, the treating temperature is in the range of usually 30 to 55° C., preferably 35 to 45° C., and the treating time is in the range of usually 2 to 40 seconds, preferably 2 to 30 seconds.

By the above treatment, such a protrusion 21a of the base metal remaining on the side surface of the wiring pattern and such a base metal layer 21b remaining between the wirings as shown in FIG. 7(A) are dissolved and removed, as shown in FIG. 7(B), and the shortest distance W between the base metal layers constituting the wiring patterns is widened (see FIG. 1(I), FIG. 1(J), FIG. 2(I), FIG. 2(J), FIG. 7, etc.).

The shortest distance W between the base metal layers varies depending upon a wiring pitch, and in case of a wiring pitch of, for example, 30 μm (line width designed: 15 μm, space width designed: 15 μm), the shortest distance W between the base metal layers, as actually measured from an electron microscope photograph (SEM photograph), is in the range of 5 to 18 μm. This distance W is 33 to 120% of the space width designed, and the shortest distance W frequently becomes 10 to 16 μm. In case of a wiring pitch of 100 μm (line width designed: 50 μm, space width designed: 50 μm), the shortest distance W is frequently in the range of 10 to 120% of the space width designed.

The wiring pattern is plated for the purpose of preventing oxidation or forming an alloy layer in the bonding of IC chip or the like, and in this case, the shortest distance W between the wiring edges of the wiring patterns including the base metal layer and the plating layer is preferably not less than 5 μm.

The expression “the protrusion 21a of the base metal is dissolved and removed” means that as a result of dissolving, the distance from the boundary between the base metal layer at the root of the protrusion and the insulating film to the tip of the protrusion, which is designated by “SA” in FIG. 7, comes to be in the range of 0 to 6 μm (0 to 40% of the space width designed), preferably 0 to 5 μm, more preferably 0 to 3 μm, most preferably 0 to 2 μm, in case of a wiring pitch of 30 μm, though it varies depending upon the wiring pitch. When the distance SA is in this range, such a part is not called “protrusion” in the present invention.

FIG. 7(C) schematically shows an embodiment of a wiring board wherein a base metal layer is exposed by microetching.

After the treatment with the first treating solution capable of dissolving Ni is carried out, the Cu pattern is selectively microetched by any one of a potassium persulfate (K₂S₂O₈) solution, a sodium persulfate (Na₂S₂O₈) solution and a solution of sulfuric acid+H₂O₂ to selectively slightly dissolve (retreat) the pattern composed of the conductive metal and thereby project the base metal layer (seed layer) from the conductive metal layer. However, if the contact time with the etching solution is long in this microethcing step, copper that is a conductive metal for forming the wiring pattern is dissolved in a large amount and the wiring pattern itself is thinned, so that the contact time of the wiring pattern with the etching solution in the microethcing step is in the range of usually 2 to 60 seconds, preferably 10 to 45 seconds.

After the conductive metal layer 20 is retreated as above in the microethcing step, the surface of the insulting film 11 where the wiring pattern has not been formed is finally treated with a second treating solution capable of dissolving Cr and the insulating film such as a polyimide film. That is to say, in the present invention, a treatment with a first treating solution capable of dissolving Ni is carried out, then microetching is carried out when needed, and then a treatment with a second treating solution capable of dissolving a part of Cr remaining as the base metal layer (seed layer) and capable of oxidizing/passivating the undissolved Cr is carried out, whereby most of the base metal layer 12 can be removed and Cr remaining in a thickness of several tens Å on the surface of the insulating film 11 can be oxidized and passivated. Accordingly, by the use of the second treating solution, the base metal layer 12 can be removed and the residual Cr can be oxidized and passivated, as shown in FIG. 1(I) and FIG. 2(I).

Examples of the second treating solutions employable herein include an aqueous solution of potassium permanganate+KOH, a potassium bichromate aqueous solution and an aqueous solution of sodium permanganate+NaOH. When the aqueous solution of potassium permanganate+KOH is used, the concentration of potassium permanganate is in the range of usually 10 to 60 g/liter, preferably 25 to 55 g/liter, and the concentration of KOH is in the range of preferably 10 to 30 g/liter. In the treatment with the second treating solution in the invention, the treating temperature is in the range of usually 40 to 70° C., preferably 50 to 65° C., and the treating time is in the range of usually 10 to 60 seconds, preferably 15 to 45 seconds. By the treatment under these conditions, Cr remaining in a thickness of several Å to several tens Å on the surface of the insulating film where the wiring pattern has not been formed is oxidized and passivated to thereby increase insulation resistance. Further, the base metal layer 12 as a part of the wiring pattern and the insulating film 11 are protected by the conductive metal layer 20.

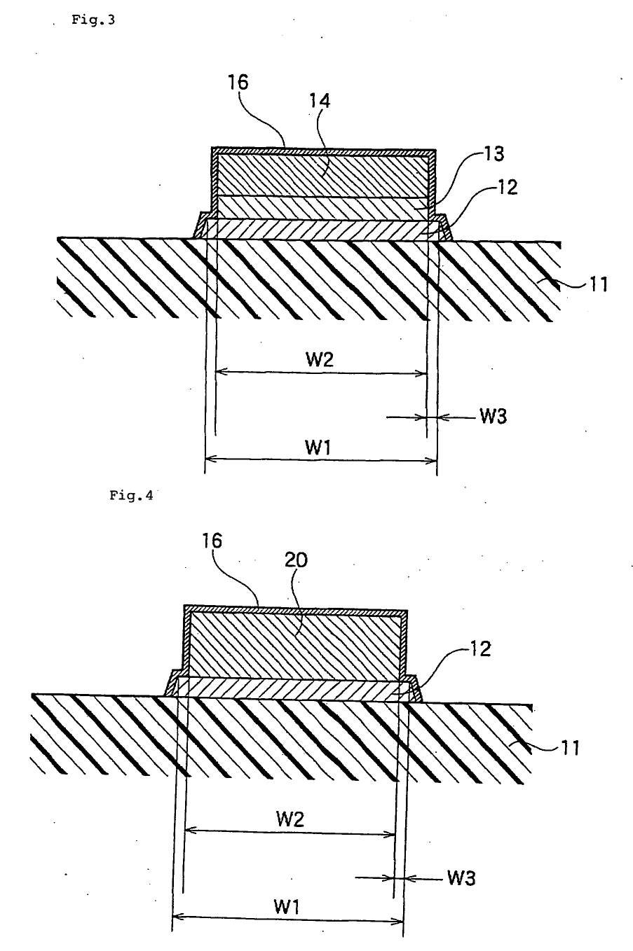

In the resulting wiring board, as shown in FIG. 3 and FIG. 4, the top width W1 of the base metal layer 12 present at the bottom of the wiring pattern is wider than the bottom width W2 of the conductive metal layer 20 (i.e., sputtering copper layer in the case where the sputtering copper layer 13 is provided), and the value of W1-W2 is in the range of 0.1 to 4.0 μm, preferably 0.4 to 2.0 μm. In other words, the width (sectional width) of the base metal layer 12 is desirably made wider than the bottom width W2 of the conductive metal layer in such a manner that the width W3 of the projected part of the base metal layer 12 on one side is in the range of usually 0.05 to 2.0 μm, preferably 0.2 to 1.0 μm.

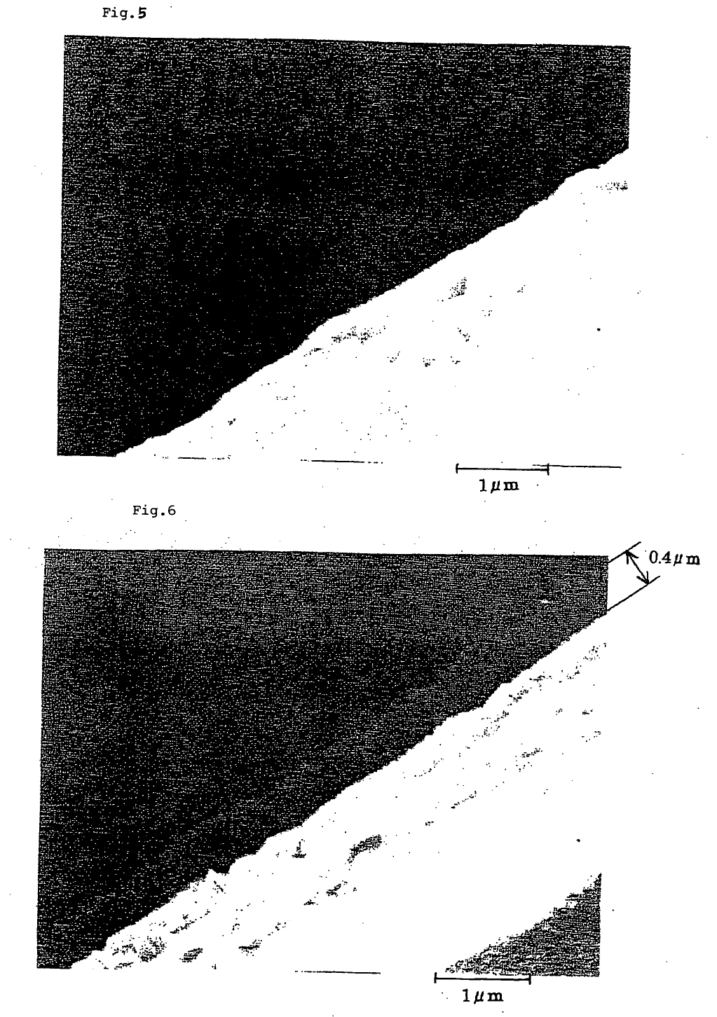

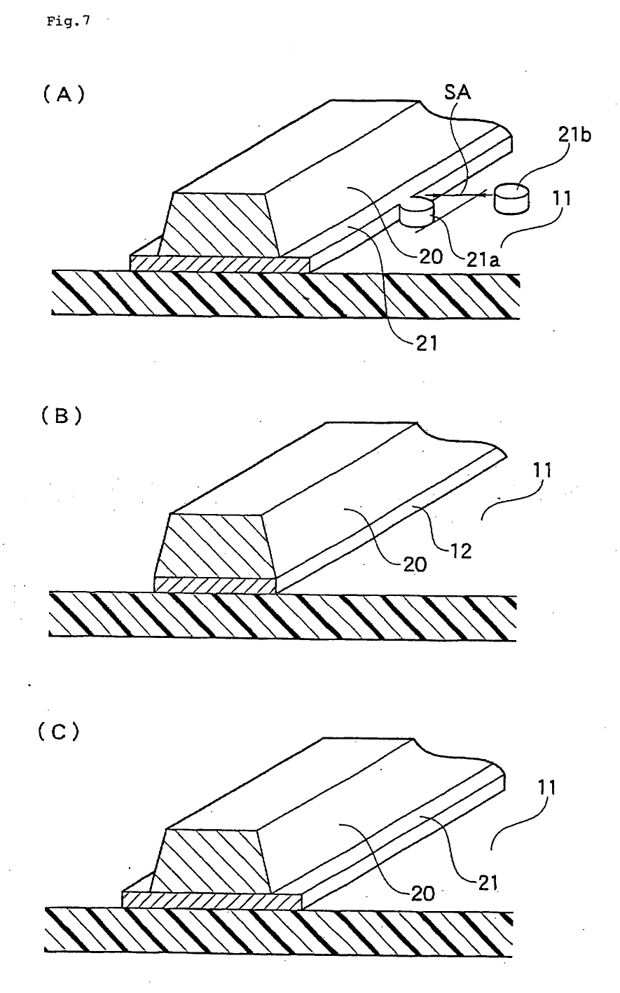

In FIG. 5 and FIG. 6, SEM photographs (EF-SEM photographs) of an edge of a wiring on the insulating film taken before and after the microetching treatment are shown. In these figures, a white portion on the lower right-hand side is a conductive metal layer (copper layer) of a wiring. When the wiring shown in FIG. 5 is subjected to microetching, a stair having a dimension controlled almost constant is formed, and the base metal layer with a uniform width (W3=about 0.4 μm) is exposed as shown in FIG. 6 (in this figure, a band ranging from the lower left-hand side to the upper right-hand side is exposed). In the SEM photograph after the microetching treatment, Ni independently present between the wiring patterns was not confirmed, but Cr was slightly observed.

After the wiring pattern is formed as above, concealing plating treatment is preferably carried out so as to conceal at least the base metal present as the side wall of the lower part of the wiring pattern. That is to say, in the printed wiring board of the invention, after formation of a wiring pattern and before formation of a solder resist layer, an exposed portion of the base metal layer 12 present at the bottom of the wiring pattern may be concealed with a concealing plating layer 16, as shown in FIG. 1(J), FIG. 2(J), FIG. 3 and FIG. 4. The concealing plating layer 16 has only to conceal at least the base metal layer 12 present at the bottom of the wiring pattern. The concealing plating layer 16, however, may be formed on the whole surface of the wiring pattern. The concealing plating layer thus formed is at least one layer selected from the group consisting of a tin plating layer, a gold plating layer, a nickel-gold plating layer, a solder plating layer, a lead-free solder plating layer, a Pd plating layer, a Ni plating layer, a Zn plating layer and a Cr plating layer. Of these, a tin plating layer, a gold plating layer, a Ni plating layer, a nickel-gold plating layer are particularly preferable in the present invention. It is also possible that the wiring pattern is partially coated with a solder resist prior to plating and the exposed portion is plated with the above-mentioned metal, as described later.

Although the thickness of the concealing plating layer can be appropriately selected according to the type of the plating method, the thickness is in the range of usually 0.005 to 5.0 μm, preferably 0.005 to 3.0 μm. It is also possible that the whole surface of the wiring pattern is plated, then the pattern is partially coated with a solder resist, and the exposed portion is further plated with the same metal. Also by forming a concealing plating layer of such a thickness, migration from the base metal layer 12 does not occur. The concealing plating layer can be formed by electroplating, electroless plating or the like.

By carrying out the concealing plating treatment of the wiring pattern as above, the passivated surface of the base metal layer present on the insulating film side of the wiring pattern is concealed with the concealing plating layer, and even if a potential difference is produced between different metals, occurrence of migration from the base metal layer can be effectively prevented because the insulation resistance between wirings is sufficiently high. Further, even when tin is used as a metal for the concealing plating, a whisker is not produced from the tin plating layer because the base metal layer 12 that is a base of the plating layer has been passivated.

The side surface of the base metal layer that forms the wiring pattern may be concealed by the concealing plating treatment as above, or the side surface of the base metal layer may not be subjected to the plating treatment. And then a solder resist is applied in such a manner that a terminal of the wiring pattern is exposed and then cured to form a solder resist layer.

After the solder resist layer is formed as above, the terminal exposed from the solder resist layer is plated. This plating is usually carried out for the purpose of bonding the terminal to an electronic part, and through this treatment, the plating layer is formed on a surface of an inner connecting terminal and on a surface of an outer connecting terminal provided on the printed wiring board.

This plating layer may be a plating layer which has been provided on the whole surface of the wiring pattern before the solder resist layer is formed. Alternatively, a first plating layer may be provided on the whole surface of the wiring pattern and a second plating layer may be provided on the terminal exposed after the solder resist layer is formed.

Examples of the plating layers include an electroless tin plating layer, a tin electroplating layer, a solder plating layer, a nickel plating layer, a nickel-gold plating layer, a Cu—Sn plating layer and a Sn—Bi plating layer. The plating layer may be the same as or different from the concealing plating layer to conceal the base metal layer that forms the wiring pattern. Even if the base metal layer is not sufficiently covered with the concealing plating layer and is porous, or even if the concealing plating layer is extremely thin and porous, migration does not occur by virtue of this treatment. The concealing plating layer formed on the whole surface of the wiring pattern may be used also as a plating layer for usual bonding.

The thickness of the plating layer thus formed is in the range of usually 0 to 5 μm, preferably 0 to 3 μm.

In the plating layer, the metal that is in contact with the base metal layer and/or the conductive metal layer is sometimes alloyed with the metals of these layers when heating is carried out to cure the solder resist layer. For example, in the case where a tin plating layer is formed, a Cu—Sn alloy layer is formed at the interface between the tin plating layer and the conductive metal layer (particularly copper layer). However, if alloying does not proceed on the outermost surface of the plating layer formed on the terminal, said surface being to be bonded to an outer electrode, the original metal composition is maintained. Further, even if a tin plating layer is formed as above, a whisker is not produced from the tin plating layer because the base metal layer 12 that is a base of the plating layer has been passivated.

After the plating layer is formed as above, an electronic part is electrically connected to the inner connecting terminal, and then the electronic part is coated with a resin, whereby a circuit device of the invention can be obtained.

In the printed wiring board or the circuit device of the invention, variation of an electrical resistance value between the wiring patterns caused by migration or the like is extremely small. That is to say, in the printed wiring board and the circuit device of the invention, migration hardly occurs and substantial variation in the insulation resistance between before and after application of a voltage is not observed, so that they have remarkably high reliability.

The printed wiring board of the invention is suitable as a printed wiring board having a wiring pattern (or lead) width of not more than 30 μm, preferably 25 to 5 μm, and a pitch width of not more than 50 μm, preferably 40 to 10 μm. Examples of such printed wiring boards include printed wiring board (PWB), TAB (tape automated bonding) tape, COF (chip on film) tape, CSP (chip size package) tape, BGA (ball grid array) tape, μ-BGA (μ-ball grid array) tape and FPC (flexible printed circuit). The printed wiring board of the invention described above is a printed wiring board in which a wiring pattern is formed on a surface of a polyimide film that is an insulating film, but on a part of the wiring pattern, an electronic component may be mounted. The electronic component thus mounted is usually sealed with a sealing resin to form a circuit device.

### EXAMPLES

The printed wiring board of the invention and the process for producing the same are further described with reference to the following examples, but it should be construed that the invention is in no way limited to those examples.

All the insulation resistance values described in the following examples and comparative example are values measured at room temperature outside a constant-temperature constant-humidity vessel.

### Example 1

One surface of a polyimide film having an average thickness of 38 μm (available from Ube Industries, Ltd., Upirex S) was subjected to roughening treatment by back sputtering, and then a nickel-chromium alloy was sputtered under the following conditions to form a chromium-nickel alloy layer having an average thickness of 40 nm as a base metal layer.

That is to say, the polyimide film of 38 μm thickness was treated at 100° C. and 3×10⁻⁵ Pa for 10 minutes to perform degassing, and then a chromium-nickel alloy was sputtered under the sputtering conditions of 100° C. and 0.5 Pa.

On the base metal layer formed as above, copper was further sputtered under the conditions of 100° C. and 0.5 Pa to form a sputtering copper layer having an average thickness of 300 nm.

On the surface of the sputtering copper layer formed as above, copper was deposited by electroplating to form an electrolytic copper layer (electroplating copper layer) having a thickness of 8 μm.

The surface of the electrolytic copper layer thus formed was coated with a photosensitive resin, and the photosensitive resin was exposed and developed to form a pattern of a comb-shaped electrode in such a manner that a wiring pitch became 30 μm (line width: 15 μm, space width: 15 μm). Using the pattern as a masking material, the copper layer was etched for 30 seconds with a cupric chloride etching solution containing 100 g/liter of HCl and having a concentration of 12% to form a wiring pattern.

Then, a treatment with a NaOH+Na₂CO₃ solution was carried out at 40° C. for 30 seconds to remove the masking material made of the photosensitive resin present on the wiring pattern, and then a treatment with a K₂S₂O₈+H₂SO₄ solution as a pickling solution was carried out at 30° C. for 10 seconds to pickle the copper layer and the base metal layer (Ni—Cr alloy).

Subsequently, the resulting film carrier was treated with a solution containing 17 g/liter of HCl and 17 g/liter of H₂SO₄ as a first treating solution at 50° C. for 30 seconds to dissolve Ni of the base metal layer composed of a Ni—Cr alloy.

Then, using a microetching solution of K₂S₂O₈+H₂SO₄, the Cu conductor was dissolved in a width (W3) of 0.3 μm (retreat of Cu conductor).

Further, a treatment with a solution containing 40 g/liter of potassium permanganate and 20 g/liter of KOH as a second treating solution was carried out at 65° C. for 30 seconds to dissolve Cr contained in the base metal layer. This second treating solution dissolves and removes chromium contained in the base metal layer, and besides, it can oxidize and passivate chromium remaining in a trace amount.

After the wiring pattern was formed as above, the wiring pattern was subjected to electroless tin plating in a thickness of 0.01 μm.

After the wiring pattern was concealed with the tin plating layer as above, a solder resist layer was formed in such are manner that a connecting terminal and an outer connecting terminal were exposed.

Thereafter, the inner connecting terminal and the outer connecting terminal exposed from the solder resist layer were subjected to Sn plating in a thickness of 0.5 μm, and they were heated to form a prescribed pure Sn layer (Sn plating total thickness: 0.51 μm, pure Sn layer thickness: 0.25 μm). After the Sn plating, 10 different points selected at random were observed by FE-SEM. As a result, the shortest distance between the base metal layers of the wirings was 15.5 μm, and a protrusion of a base metal layer and a base metal layer independently present between the wirings were not observed.

To the printed wiring board with a comb-shaped electrode prepared as above was applied a voltage of 40 V under the conditions of 85° C. and 85% RH to perform a 1000-hr conduction test (HHBT). This conduction test is an accelerating test, and when a period of time until occurrence of short-circuit, for example, a period of time until the insulation resistance value becomes less than 1×10⁸Ω, is shorter than 1000 hours, the printed wiring board cannot be used as a general board. The insulation resistance of the printed wiring board of this example measured before the insulation reliability test was higher than that of the comparative example and was 4×10¹⁴Ω, while the insulation resistance measured after the insulation reliability test was 2×10¹⁴Ω, so that a substantial difference in the insulation resistance attributable to the application of a voltage was not confirmed between them.

The result is set forth in Table 1.

### Example 2

One surface of a polyimide film having an average thickness of 38 μm (available from Ube Industries, Ltd., Upirex S) was subjected to roughening treatment by back sputtering, and then a nickel-chromium alloy was sputtered under the following conditions to form a chromium-nickel alloy layer having an average thickness of 40 nm as a base metal layer.

That is to say, the polyimide film of 38 μm thickness was treated at 100° C. and 3×10⁻⁵ Pa for 10 minutes to perform degassing, and then a chromium-nickel alloy was sputtered under the sputtering conditions of 100° C. and 0.5 Pa.

On the base metal layer formed as above, copper was deposited by electroplating to form an electrolytic copper layer (electroplating copper layer, conductive metal layer) having a thickness of 8 μm.

The surface of the electrolytic copper layer thus formed was coated with a photosensitive resin, and the photosensitive resin was exposed and developed to form a pattern of a comb-shaped electrode in such a manner that a wiring pitch became 30 μm (line width: 15 μm, space width: 15 μm). Using the pattern as a masking material, the copper layer was etched for 30 seconds with a cupric chloride etching solution containing 100 g/liter of HCl and having a concentration of 12% to form a wiring pattern.

Then, a treatment with a NaOH+Na₂CO₃ solution was carried out at 40° C. for 30 seconds to remove the masking material made of the photosensitive resin present on the wiring pattern, and then a treatment with a K₂S₂O₈+H₂SO₄ solution as a pickling solution was carried out at 30° C. for 10 seconds to pickle the copper layer and the base metal layer (Ni—Cr alloy).

Subsequently, the resulting film carrier was treated with a solution containing 17 g/liter of HCl and 17 g/liter of H₂SO₄ as a first treating solution at 50° C. for 30 seconds to dissolve Ni of the base metal layer composed of a Ni—Cr alloy.

Then, using a microetching solution of K₂S₂O₈+H₂SO₄, the Cu conductor was dissolved in a width (W3) of 0.3 μm (retreat of Cu conductor).

Further, a treatment with a solution containing 40 g/liter of potassium permanganate and 20 g/liter of KOH as a second treating solution was carried out at 65° C. for 30 seconds to dissolve Cr contained in the base metal layer. This second treating solution dissolves and removes chromium contained in the base metal layer, and besides, it can oxidize and passivate chromium remaining in a trace amount.

After the wiring pattern was formed as above, the wiring pattern was subjected to electroless tin plating in a thickness of 0.01 μm.

After the wiring pattern was concealed with the tin plating layer as above, a solder resist layer was formed in such a manner that a connecting terminal and an outer connecting terminal were exposed.

Thereafter, the inner connecting terminal and the outer connecting terminal exposed from the solder resist layer were subjected to Sn plating in a thickness of 0.5 μm, and they were heated to form a prescribed pure Sn layer (Sn plating total thickness: 0.51 μm, pure Sn layer thickness: 0.25 μm). After the Sn plating, 10 different points selected at random were observed by FE-SEM. As a result, the shortest distance between the base metal layers of the wirings was 15.5 μm, and a protrusion of a base metal layer and a base metal layer independently present between the wirings were not observed.

To the printed wiring board with a comb-shaped electrode prepared as above was applied a voltage of 40 V under the conditions of 85° C. and 85% RH to perform a 1000-hr conduction test (HHBT). The insulation resistance of the printed wiring board of this example measured before the insulation reliability test was higher than that of the comparative example and was 4×10¹⁴Ω, while the insulation resistance measured after the insulation reliability test was 3×10¹⁴Ω, so that a substantial difference in the insulation resistance attributable to the application of a voltage was not confirmed between them.

The result is set forth in Table 1.

### Example 3

A polyimide film having an average thickness of 75 μm (available from Ube Industries, Ltd., Upirex S) was used. One surface of the polyimide film was subjected to roughening treatment by back sputtering, and then a nickel-chromium alloy was sputtered in the same manner as in Example 1 to form a chromium-nickel alloy layer having an average thickness of 30 nm as a base metal layer.

On the base metal layer formed as above, copper was sputtered in the same manner as in Example 1 to form a sputtering copper layer having an average thickness of 200 nm.

On the surface of the sputtering copper layer formed as above, copper was deposited by electroplating to form an electrolytic copper layer having a thickness of 8 μm.

The surface of the copper layer thus formed was coated with a photosensitive resin, and the photosensitive resin was exposed and developed to form a pattern of a comb-shaped electrode in such a manner that a wiring pitch became 30 μm. Using the pattern as a masking material, the copper layer was etched for 30 seconds with a cupric chloride etching solution containing 100 g/liter of HCl and having a concentration of 12% to form a wiring pattern.

Then, a treatment with a NaOH+Na₂CO₃ solution was carried out at 40° C. for 30 seconds to remove the masking material made of the photosensitive resin present on the wiring pattern, and then a treatment with a HCl solution as a pickling solution was carried out at 30° C. for 10 seconds to pickle the copper layer and the base metal layer (Ni—Cr alloy).

Subsequently, a treatment with a solution containing 13 g/liter of HCl and 13 g/liter of H₂SO₄ as a first treating solution was carried out at 55° C. for 20 seconds to dissolve Ni of the base metal layer composed of a Ni—Cr alloy.

Then, using a microetching solution of K₂S₂O₈+H₂SO₄, Cu was etched in the depth direction (W3=0.5 μm) at 30° C. for 10 seconds.

Further, a treatment with a solution containing 40 g/liter of KMnO₄ and 20 g/liter of KOH as a second treating solution was carried out at 65° C. for 30 seconds.

After the wiring pattern was formed as above, a solder resist layer was formed in such a manner that a connecting terminal and an outer connecting terminal were exposed.

On the other hand, the inner connecting terminal and the outer connecting terminal exposed from the solder resist layer were subjected to Sn plating in a thickness of 0.45 μm, and they were heated to form a prescribed pure Sn layer (pure Sn layer thickness: 0.2 μm). After the Sn plating, 10 different points selected at random were observed by FE-SEM. As a result, the shortest distance between the base metal layers of the wirings was 16.0 μm, and a protrusion of a base metal layer and a base metal layer independently remaining between the wirings were not observed.

To the printed wiring board with a comb-shaped electrode prepared as above was applied a voltage of 40 V under the conditions of 85° C. and 85% RH to perform a 1000-hr conduction test (HHBT). The insulation resistance of the printed wiring board of this example measured before the insulation reliability test was higher than that of the comparative example and was 5×10¹⁴Ω, while the insulation resistance measured after the insulation reliability test was 3×10¹⁴Ω, so that a substantial difference in the insulation resistance attributable to the application of a voltage was not confirmed between them.

The result is set forth in Table 1.

### Example 4

A polyimide film having an average thickness of 75 μm (available from Ube Industries, Ltd., Upirex S) was used. One surface of the polyimide film was subjected to roughening treatment by back sputtering, and then a nickel-chromium alloy was sputtered in the same manner as in Example 1 to form a chromium-nickel alloy layer having an average thickness of 30 nm as a base metal layer.

On the surface of the base metal layer formed as above, copper was deposited by electroplating to form an electrolytic copper layer (conductive metal layer) having a thickness of 8 μm.

The surface of the copper layer thus formed was coated with a photosensitive resin, and the photosensitive resin was exposed and developed to form a pattern of a comb-shaped electrode in such a manner that a wiring pitch became 30 μm. Using the pattern as a masking material, the copper layer was etched for 30 seconds with a cupric chloride etching solution containing 100 g/liter of HCl and having a concentration of 12% to form a wiring pattern.

Then, a treatment with a NaOH+Na₂CO₃ solution was carried out at 40° C. for 30 seconds to remove the masking material made of the photosensitive resin present on the wiring pattern, and then a treatment with a HCl solution as a pickling solution was carried out at 30° C. for 10 seconds to pickle the copper layer and the base metal layer (Ni—Cr alloy).

Subsequently, a treatment with a solution containing 13 g/liter of HCl and 13 g/liter of H₂SO₄ as a first treating solution was carried out at 55° C. for 20 seconds to dissolve Ni of the base metal layer composed of a Ni—Cr alloy.

Then, using a microetching solution of K₂S₂O₈+H₂SO₄, Cu was etched in the depth direction (W3=0.5 μm) at 30° C. for 10 seconds.

Further, a treatment with a solution containing 40 g/liter of KMnO₄ and 20 g/liter of KOH as a second treating solution was carried out at 65° C. for 30 seconds.

After the wiring pattern was formed as above, a solder resist layer was formed in such a manner that a connecting terminal and an outer connecting terminal were exposed.

On the other hand, the inner connecting terminal and the outer connecting terminal exposed from the solder resist layer were subjected to Sn plating in a thickness of 0.45 μm, and they were heated to form a prescribed pure Sn layer (pure Sn layer thickness: 0.2 μm). After the Sn plating, 10 different points selected at random were observed by FE-SEM. As a result, the shortest distance between the base metal layers of the wirings was 16.0 μm, and a protrusion of a base metal layer and a base metal layer independently present between the wirings were not observed.

To the printed wiring board with a comb-shaped electrode prepared as above was applied a voltage of 40 V under the conditions of 85° C. and 85% RH to perform a 1000-hr conduction test (HHBT). The insulation resistance of the printed wiring board of this example measured before the insulation reliability test was higher than that of the comparative example and was 5×10¹⁴Ω, while the insulation resistance measured after the insulation reliability test was 2×10¹⁴Ω, so that a substantial difference in the insulation resistance attributable to the application of a voltage was not confirmed between them.

The result is set forth in Table 1.

### Example 5

A printed wiring board was prepared in the same manner as in Example 1, except that the Cu conductor was dissolved in the depth direction by 1.0 μm by means of microetching.

To the printed wiring board with a comb-shaped electrode prepared as above was applied a voltage of 40 V under the conditions of 85° C. and 85% RH to perform a 1000-hr conduction test (HHBT). The insulation resistance of the printed wiring board of this example measured before the insulation reliability test was higher than that of the comparative example and was 6×10¹⁴Ω, while the insulation resistance measured after the insulation reliability test was 5×10¹⁴Ω, so that a substantial difference in the insulation resistance attributable to the application of a voltage was not confirmed between them.

The result is set forth in Table 1.

### Example 6

A printed wiring board was prepared in the same manner as in Example 2, except that the Cu conductor was dissolved in the depth direction by 1.0 μm by means of microetching.

To the printed wiring board with a comb-shaped electrode prepared as above was applied a voltage of 40 V under the conditions of 85° C. and 85% RH to perform a 1000-hr conduction test (HHBT). The insulation resistance of the printed wiring board of this example measured before the insulation reliability test was higher than that of the comparative example and was 6×10¹⁴Ω, while the insulation resistance measured after the insulation reliability test was 5×10¹⁴Ω, so that a substantial difference in the insulation resistance attributable to the application of a voltage was not confirmed between them.

The result is set forth in Table 1.

### Comparative Example 1

One surface of a polyimide film having a thickness of 25 μm (available from Dupont-Toray Co., Ltd., trade name: Kapton 100EN) was treated in a 30% hydrazine-KOH aqueous solution for 60 seconds. Thereafter, the polyimide film was washed with pure water for 10 minutes and dried at room temperature. The polyimide film was then placed in a vacuum deposition device. After plasma treatment, a Ni—Cr alloy of 40 nm was deposited by sputtering, and then a copper layer of 8 μm was further formed by plating to obtain a metal coated polyimide substrate.

The resulting substrate was treated with a ferric chloride solution of 40° Be (Baume) to form a comb-shaped pattern having a pitch of 40 μm (line width: 20 μm, space width: 20 μm), then washed with an aqueous solution of potassium permanganate (0.5% by weight) and potassium hydroxide (0.5% by weight) at 35° C., further washed with water and dried. To the resulting sample, a bias of 40 V was applied in a constant-temperature constant-humidity vessel of an 85° C./85% RH atmosphere to perform an insulation reliability test (HHBT). The retention time was 1000 hours or more. Although the insulation resistance at the beginning of the insulation reliability test was 5×10¹²Ω, the insulation resistance measured after a lapse of 1000 hours was lowered to 2×10¹⁰Ω, so that lowering of the insulation resistance with time attributable to the application of a voltage was confirmed.

TABLE 1

| | | Base metal | | | | |
|---|---|---|---|---|---|---|
| | | layer | Sputtering layer | | plating layer | |
| | Polyimide | Nickel-chromium | Metal | Thickness | Metal | Thickness |
| Ex. 1 | 38 μm | 40 nm | copper | 300 nm | electrolytic | 8 μm |
| | | | | | copper | |
| Ex. 2 | 38 μm | 40 nm | — | — | electrolytic | 8 μm |
| | | | | | copper | |
| Ex. 3 | 75 μm | 30 nm | copper | 200 nm | electrolytic | 8 μm |
| | | | | | copper | |
| Ex. 4 | 75 μm | 30 nm | — | — | electrolytic | 8 μm |
| | | | | | copper | |
| Ex. 5 | 50 μm | 40 nm | copper | 300 nm | electrolytic | 8 μm |
| | | | | | copper | |
| Ex. 6 | 50 μm | 40 nm | — | — | electrolytic | 8 μm |
| | | | | | copper | |
| Comp. | 25 μm | 40 nm | copper | 300 nm | electrolytic | 8 μm |
| Ex. 1 | | | | | copper | |

| | Etching agent | | | |
|---|---|---|---|---|
| | | | Microetching | |
| | | First treating | Treated depth of Cu | Second treating |
| | Cu etching | solution | layer | solution |
| Ex. 1 | cupric | 15% HCl + 15% H₂SO₄ | K₂S₂O₈ + H₂SO₄ | KMnO₄ + KOH |
| | chloride | | 0.3 μm | |
| Ex. 2 | cupric | 15% HCl + 15% H₂SO₄ | K₂S₂O₈ + H₂SO₄ | KMnO₄ + KOH |
| | chloride | | 0.3 μm | |
| Ex. 3 | cupric | 12% HCl + 12% H₂SO₄ | K₂S₂O₈ + H₂SO₄ | KMnO₄ + KOH |
| | chloride | | 0.5 μm | |
| Ex. 4 | cupric | 12% HCl + 12% H₂SO₄ | K₂S₂O₈ + H₂SO₄ | KMnO₄ + KOH |
| | chloride | | 0.5 μm | |
| Ex. 5 | cupric | 15% HCl + 15% H₂SO₄ | K₂S₂O₈ + H₂SO₄ | KMnO₄ + KOH |
| | chloride | | 1.0 μm | |
| Ex. 6 | cupric | 15% HCl + 15% H₂SO₄ | K₂S₂O₈ + H₂SO₄ | KMnO₄ + KOH |
| | chloride | | 1.0 μm | |
| Comp. | ferric | none | KMnO₄ + KOH | |
| Ex. 1 | chloride | | | |

| | Concealing deposited layer | HHBT |
|---|---|---|
| | Metal | Insulation resistance |
| | Thickness | after 1000 hours |
| Ex. 1 | Sn 0.01 μm | 2 × 10¹⁴ Ω |
| Ex. 2 | Sn 0.01 μm | 3 × 10¹⁴ Ω |
| Ex. 3 | none | 3 × 10¹⁴ Ω |
| Ex. 4 | none | 2 × 10¹⁴ Ω |
| Ex. 5 | Sn 0.01 μm | 5 × 10¹⁴ Ω |
| Ex. 6 | Sn 0.01 μm | 5 × 10¹⁴ Ω |
| Comp. | none | 2 × 10¹⁰ Ω |
| Ex. 1 | | |

### INDUSTRIAL APPLICABILITY

In the printed wiring board of the invention, the side surface of the base metal layer that forms a wiring pattern is concealed with a plating layer, and therefore, migration from the base metal layer hardly occurs. In the circuit device wherein an electronic part is mounted on such a printed wiring board, stable insulation between the wiring patterns is maintained for a long period of time.

Further, there is obtained by the invention a printed wiring board in which the insulation resistance between the wiring patterns does not vary even by continuously applying a voltage for a long period of time and which is electrically very stable in spite of a lapse of time.

1. A printed wiring board having, on at least one surface of an insulating film, a wiring pattern comprising a base metal layer and a conductive metal layer formed on the base metal layer, wherein:
in a section of the wiring pattern, a width of a bottom of the conductive metal layer is smaller than a width of a top of the base metal layer.

2. The printed wiring board as claimed in claim 1, wherein an average distance at a narrowest part between the wiring pattern and a neighboring wiring pattern formed on the insulating film is in a range of 5 to 40 μm, the base metal layer which is in contact with the insulating film and constitutes the wiring pattern is projected following a contour of the conductive metal layer so as to rim the wiring pattern composed of the conductive metal layer, wherein a discontinuous protrusion is not formed in the wiring pattern composed of the base metal layer projected following the contour of the conductive metal layer, and an independent base metal layer is not substantially present on the insulating film between wiring patterns.

3. The printed wiring board as claimed in claim 1, wherein the base metal layer comprises an alloy or a laminate comprising two or more metals having different properties.

4. The printed wiring board as claimed in claim 3, wherein the base metal layer is a layer containing Ni and/or Cr or an alloy layer of these metals.

5. The printed wiring board as claimed in claim 1, wherein a sectional shape of the wiring pattern has a stair formed by the base metal layer, and the stair of the base metal layer is formed so as to be projected following a contour of the conductive metal layer around the wiring pattern composed of the conductive metal layer.

6. The printed wiring board as claimed in claim 1, wherein in the section of the wiring pattern, the bottom width of the conductive metal layer is smaller by 0.1 to 4 μm than a total width of a contouring projected part of the base metal layer and the bottom of the conductive metal layer.

7. The printed wiring board as claimed in claim 1, wherein an exposed surface of the base metal layer projected following a contour of the conductive metal layer around the wiring pattern is coated with a concealing plating layer.

8. The printed wiring board as claimed in claim 7, wherein the concealing plating layer is at least one plating layer selected from the group consisting of a tin plating layer, a gold plating layer, a nickel-gold plating layer, a solder plating layer, a lead-free solder plating layer, a Pd plating layer, a Ni plating layer, a Zn plating layer and a Cr plating layer.

9. The printed wiring board as claimed in claim 1, wherein a plating layer is formed on a whole surface of the wiring pattern and a solder resist layer is formed thereon except on a terminal of the wiring pattern.

10. The printed wiring board as claimed in claim 1, wherein a plating layer is formed on a whole surface of the wiring pattern, a solder resist layer is formed thereon excep ton a terminal of the wiring pattern, and a second plating layer is formed on the terminal.

11. The printed wiring board as claimed in claim 1, wherein a solder resist layer is formed on the wiring pattern except on a terminal of the wiring pattern, and a plating layer is formed on the terminal exposed from the solder resist layer.

12. The printed wiring board as claimed in claim 1, wherein the conductive metal layer is formed on the base metal layer through a sputtering copper layer.

13. A process for producing a printed wiring board, comprising the steps of depositing a base metal layer on at least one surface of an insulating film, then depositing a conductive metal on the base metal layer surface to form a conductive metal layer and then selectively etching the base metal layer and the conductive metal layer to form a wiring pattern, wherein the base metal layer and the conductive metal layer are brought into contact with an etching solution capable of dissolving the conductive metal to form a wiring pattern, and thereafter the resultant is brought into contact with a first treating solution capable of dissolving the metal for forming the base metal layer, then brought into contact with a microetching solution capable of selectively dissolving the conductive metal and then brought into contact with a second treating solution having a different chemical composition from the first treating solution and acting on the base metal layer-forming metal with higher selectivity than on the conductive metal.

14. The process for producing a printed wiring board as claimed in claim 13, wherein the second treating solution not only selectively dissolves and removes the base metal layer but also passivates the residual base metal layer-forming metal.

15. The process for producing a printed wiring board as claimed in claim 13, wherein the wiring pattern formed by bringing the base metal layer and the conductive metal layer into contact with the etching solution capable of dissolving the conductive metal is subjected to microetching prior to the contact with the first treating solution.

16. The process for producing a printed wiring board as claimed in claim 13, comprising the steps of depositing a base metal layer containing Ni and Cr on at least one surface of an insulating film, then depositing a conductive metal on the base metal layer surface to form a conductive metal layer and then selectively etching the base metal layer and the conductive metal layer to form a wiring pattern, wherein the base metal layer and the conductive metal layer are brought into contact with an etching solution capable of dissolving the conductive metal to form a wiring pattern, thereafter the resultant is brought into contact with a first treating solution capable of dissolving Ni of the metals for forming the base metal layer, and then the wiring patterns formed is brought into contact with a microetching solution capable of dissolving the conductive metal to retreat the conductive metal layer and thereby expose the base metal layer following the contour of the conductive metal layer around the wiring pattern and then brought into contact with a second treating solution capable of dissolving Cr or converting a trace amount of the residual Cr into a non-conductive film.

17. The process for producing a printed wiring board as claimed in claim 13, wherein after the wiring pattern is brought into contact with the second treating solution, a concealing plating layer is formed so as to cover at least the base metal layer of the wiring pattern.

18. The process for producing a printed wiring board as claimed in claim 17, wherein the concealing plating layer is at least one plating layer selected from the group consisting of a tin plating layer, a gold plating layer, a nickel-gold plating layer, a solder plating layer, a lead-free solder plating layer, a Pd plating layer, a Ni plating layer, a Zn plating layer and a Cr plating layer.

19. The process for producing a printed wiring board as claimed in claim 13, wherein the conductive metal layer is formed on the base metal layer through a sputtering copper layer.

20. A circuit device comprising the printed wiring board of claim 1 and an electronic part mounted thereon.
